(19) United States
(12) Patent Application Publication
(10) Pub. No.: US 2010/0303354 A1
(43) Pub. Date: Dec. 2, 2010

(54) EFFICIENT CODING OF PROBABILITY DISTRIBUTIONS FOR IMAGE FEATURE DESCRIPTORS

(75) Inventor: Yuriy Reznik, San Diego, CA (US)

Correspondence Address: QUALCOMM INCORPORATED, 5775 MOREHOUSE DR., SAN DIEGO, CA, 92121, US

(73) Assignee: QUALCOMM Incorporated, San Diego, CA (US)

(21) Appl. No.: 12/790,265

(22) Filed: May 28, 2010

Related U.S. Application Data
(60) Provisional application No. 61/182,862, filed on Jun. 1, 2009.

(51) Int. Cl. G06K 9/00; H03M 7/00; H03M 7/40; G06K 9/46

(52) U.S. Cl. 382/168; 341/107; 341/67; 382/232

(57) ABSTRACT

A method for encoding or compressing probability distributions is disclosed. A first mapping of probability distribution of samples to the types from the predefined set of types is generated. A second mapping of the types in the predefined set of types to lexicographic indexes from the index space is generated. A probability distribution is quantized as a type from the predefined set of types. The type is then mapped to a lexicographic index from the index space that spans the predefined set of types. A code for the lexicographic index is then transmitted and/or stored as part of a feature descriptor.

### CLAIM OF PRIORITY UNDER 35 U.S.C. §119

The present Application for patent claims priority to U.S. Provisional Application No. 61/182,862 entitled “Coding Distributions” filed Jun. 1, 2009, assigned to the assignee hereof and hereby expressly incorporated by reference herein.

### BACKGROUND

1. Field

The following description generally relates to object detection methodologies and, more particularly, to efficiently coding of probability distributions for local feature descriptors.

2. Background

Various applications may benefit from having a machine or processor that is capable of identifying objects in a visual representation (e.g., an image or picture). The fields of computer vision and/or object detection attempt to provide techniques and/or algorithms that permit identifying objects or features in an image, where an object or feature may be characterized by descriptors identifying one or more keypoints. Generally, this may involve identifying points of interest (also called keypoints) in an image for the purpose of feature identification, image retrieval, and/or object recognition. Preferably, the keypoints may be selected and/or processed such that they are invariant to image scale changes and/or rotation and provide robust matching across a substantial range of distortions, changes in point of view, and/or noise and change in illumination. Further, in order to be well suited for tasks such as image retrieval and object recognition, the feature descriptors may preferably be distinctive in the sense that a single feature can be correctly matched with high probability against a large database of features from many images.

After the keypoints in an image are detected and located, they may be identified or described by using various descriptors. For example, descriptors may descriptions of the visual features of the content in images, such as shape, color, texture, rotation, and/or motion, among other image characteristics. The individual features corresponding to the keypoints and represented by the descriptors are then matched to a database of features from known objects. Therefore, a correspondence searching system can be separated into three modules: keypoint detector, feature descriptor, and correspondence locator. In these three logical modules, the descriptor's construction complexity and dimensionality have direct and significant impact on the performance of the feature matching system.

A number of algorithms, such as Scale Invariant Feature Transform (SIFT), have been developed to first compute such keypoints and then proceed to extract one or more localized features around the keypoints. This is a first step towards detection of particular objects in an image and/or classifying the queried object based on the local features. SIFT is one approach for detecting and extracting local feature descriptors that are reasonably invariant to changes in illumination, image noise, rotation, scaling, and small changes in viewpoint. The feature detection stages for SIFT include: (a) scale-space extrema detection, (b) keypoint localization, (c) orientation assignment, and/or (d) generation of keypoint descriptors. Other alternative algorithms for generating descriptors include Speed Up Robust Features (SURF), Gradient Location and Orientation Histogram (GLOH), Local Energy based Shape Histogram (LESH), Compressed Histogram of Gradients (CHoG), among others.

Such feature descriptors are increasingly finding applications in real-time object recognition, 3D reconstruction, panorama stitching, robotic mapping, video tracking, and similar tasks. Depending on the application, transmission and/or storage of feature descriptors (or equivalent) can limit the speed of computation of object detection and/or the size of image databases. In the context of mobile devices (e.g., camera phones, mobile phones, etc.) or distributed camera networks, significant communication and power resources may be spent in transmitting information (e.g., including an image and/or image descriptors) between nodes. Feature descriptor compression is hence important for reduction in storage, latency, and transmission.

Therefore, there is a need for a way to efficiently represent and/or compress feature descriptors.

### SUMMARY

The following presents a simplified summary of one or more embodiments in order to provide a basic understanding of some embodiments. This summary is not an extensive overview of all contemplated embodiments, and is intended to neither identify key or critical elements of all embodiments nor delineate the scope of any or all embodiments. Its sole purpose is to present some concepts of one or more embodiments in a simplified form as a prelude to the more detailed description that is presented later.

According to a first aspect, a method and/or device are provided for encoding a probability distribution. A mapping of probability distributions of samples to types from a predefined set of types may be generated or obtained. A mapping of the types in the predefined set of types to lexicographic indexes from an index space is then generated or obtained. Subsequently, a probability distribution may be obtained. In one example, the probability distribution may be given by a histogram. The obtained probability distribution is quantized as a type from the predefined set of types. The type is then mapped to a lexicographic index from the index space that spans the predefined set of types. A code for the lexicographic index is then transmitted (or stored) as part of a feature descriptor. The set of types may be given by a set of rational numbers

$$\{ \frac{{k}_{1}}{n} , … , \frac{{k}_{m}}{n} \} ,$$

where n is a fixed positive integer, and where k₁, . . . , kₘ are non-negative integers, such that

$${\sum }_{i = 1}^{m} {k}_{i} = n ,$$

and where m is the number of dimensions in the probability distribution. The set of types may contain M(m, n) possible types, where

$$M ( m , n ) = ( \begin{matrix}n + m - 1 \\ m - 1\end{matrix} ) ,$$

where n is the common parameter of types and m is the number of dimensions in the probability distribution.

In one example, the code may be a fixed-length code presented as a binary representation of the lexicographic index of the type. In another example, the code may be a variable-length code corresponding to a lexicographic index of the type. The code may be a variable length code based on an estimated universal probability assignment to each type. For instance, the estimated universal probability assignment to each type may be given by

$${P}_{KT} ( t ) = ( \begin{matrix}n \\ {k}_{1} , … , {k}_{m}\end{matrix} ) Γ ( \frac{m}{2} ) \frac{{\prod }_{i = 1}^{m} Γ ( {k}_{i} + \frac{1}{2} )}{{π}^{\frac{m}{2}} Γ ( n + \frac{m}{2} )} ,$$

where P_{KT}(t) is the estimated universal probability assignment for a type t,

$$( \begin{matrix}n \\ {k}_{1} , … , {k}_{m}\end{matrix} )$$

is a multinomial coefficient where n and k₁, . . . , kₘ represent parameters of type, m is the number of dimensions, and Π is the product operator, and Γ is the Gamma function. In another example, the code may be a variable length code based on a maximum likelihood probability assignment to each type. For instance, wherein the maximum likelihood probability assignment to each type may be given by

$${P}_{ML} ( t ) = ( \begin{matrix}n \\ {k}_{1} , … , {k}_{m}\end{matrix} ) {( \frac{{k}_{1}}{n} )}^{{k}_{1}} … {( \frac{{k}_{m}}{n} )}^{{k}_{m}}$$

where P_{ML}(t) is the maximum likelihood probability assignment for a type t,

$$( \begin{matrix}n \\ {k}_{1} , … , {k}_{m}\end{matrix} )$$

is a multinomial coefficient where n and k₁, . . . , kₘ represent parameters of a type, and m is the number of dimensions.

According to one implementation of the encoding method, an input image may be obtained and a Gaussian pyramid space of the input image is constructed by applying Gaussian-blur filters to the input image. A difference between two adjacent images is obtained from the Gaussian pyramid to obtain a Gaussian (DoG) space. A keypoint may be identified from the DoG space, from which a gradient distribution is generated for points adjacent to the keypoint. A probability distribution is then generated for the gradient distribution; where this probability distribution is used to obtain the lexicographic index and code. The keypoint may be a local maxima or mimina within the DoG space. A plurality of image gradients may be calculated corresponding to the keypoint, the image gradients being vectors indicating a change in the image in a vicinity of the keypoint.

According to a second aspect, a method and/or apparatus are provided for decoding a probability distribution. A mapping of lexicographic indexes from the index space to types in a predefined set of types may be generated. Additionally, a mapping of types to probability distributions may also be generated. Subsequently, a code representative of a lexicographic index within an index space may be received as part of a feature descriptor. The lexicographic index may be mapped to a type from the predefined set of types. The type may then be converted to a probability distribution. The set of types may be given by a set of rational numbers

$$\{ \frac{{k}_{1}}{n} , … , \frac{{k}_{m}}{n} \} ,$$

where n is a fixed positive integer, and where k₁, . . . , kₘ are non-negative integers, such that

$${\sum }_{i = 1}^{m} {k}_{i} = n ,$$

and where m is the number of dimensions in the probability distribution. The probability distribution may be given by a histogram, wherein the histogram is representative of a gradient distribution for points adjacent to a keypoint for a feature in an image. The set of types may contain M(m, n) possible types, where

$$M ( m , n ) = ( \begin{matrix}n + m - 1 \\ m - 1\end{matrix} ) ,$$

where n is the common parameter of types and m is the number of dimensions in the probability distribution The code may be a fixed-length code presented as a binary representation of the lexicographic index of the type. The code may also be a variable-length code corresponding to a lexicographic index of the type. In one example, the code may be a variable length code based on an estimated universal probability assignment to each type. For instance, the estimated universal probability assignment to each type may be given by

$${P}_{KT} ( t ) = ( \begin{matrix}n \\ {k}_{1} , … , {k}_{m}\end{matrix} ) Γ ( \frac{m}{2} ) \frac{{\prod }_{i = 1}^{m} Γ ( {k}_{i} + \frac{1}{2} )}{{π}^{\frac{m}{2}} Γ ( n + \frac{m}{2} )} ,$$

where P_{KT}(t) is the estimated universal probability assignment for a type t,

$$( \begin{matrix}n \\ {k}_{1} , … , {k}_{m}\end{matrix} )$$

is a multinomial coefficient where n and k₁, . . . , kₘ represent parameters of type, m is the number of dimensions, and Π is the product operator, and Γ is the Gamma function.
In another example, the code may be a variable length code based on a maximum likelihood probability assignment to each type. For instance, the maximum likelihood probability assignment to each type may be given by

$${P}_{ML} ( t ) = ( \begin{matrix}n \\ {k}_{1} , … , {k}_{m}\end{matrix} ) {( \frac{{k}_{1}}{n} )}^{{k}_{1}} … {( \frac{{k}_{m}}{n} )}^{{k}_{m}}$$

where P_{ML}(t) is the maximum likelihood probability assignment for a type t,

$$( \begin{matrix}n \\ {k}_{1} , … , {k}_{m}\end{matrix} )$$

is a multinomial coefficient where n and k₁, . . . , kₘ represent parameters of a type, and m is the number of dimensions.

### BRIEF DESCRIPTION OF THE DRAWINGS

Various features, nature, and advantages may become apparent from the detailed description set forth below when taken in conjunction with the drawings in which like reference characters identify correspondingly throughout.

FIG. 1 is a block diagram illustrating the functional stages for performing object recognition on a queried image.

FIG. 2 illustrates a difference of Gaussian (DoG) pyramid constructed by computing the difference of any two consecutive Gaussian-blurred images in the Gaussian pyramid.

FIG. 3 illustrates a more detailed view of how a keypoint may be detected.

FIG. 4 illustrates how a gradient distributions and orientation histograms may be obtained.

FIG. 5 illustrates one example for the construction and selection of types and indexes.

FIG. 6 illustrates a plot of a Rate versus Distortion (R-D) boundary achievable by type coding.

FIG. 7 illustrates several example type lattices created for ternary histograms.

FIG. 8 is a block diagram illustrating an example of a probability distribution encoder.

FIG. 9 illustrates a method for efficiently encoding probability distribution.

FIG. 10 is a block diagram illustrating an exemplary mobile device adapted to perform probability distribution encoding.

FIG. 11 is a block diagram illustrating an example of a probability distribution decoder.

FIG. 12 illustrates a method for decoding probability distributions.

FIG. 13 is a block diagram illustrating an example of an image matching device.

### DETAILED DESCRIPTION

Various embodiments are now described with reference to the drawings, wherein like reference numerals are used to refer to like elements throughout. In the following description, for purposes of explanation, numerous specific details arc set forth in order to provide a thorough understanding of one or more embodiments. It may be evident, however, that such embodiment(s) may be practiced without these specific details. In other instances, well-known structures and devices are shown in block diagram form in order to facilitate describing one or more embodiments.

A compact and/or efficient representation for feature descriptors is provided by efficiently coding probability distributions.

### Exemplary Generation of Descriptors

For purposes of illustration, various examples discussed herein may use a Scale Invariant Feature Transform (SIFT) algorithm and/or a Compressed Histogram of Gradients (CHoG) algorithm (or variations thereof) to provide some context to the examples. However, it should be clear that alternative algorithms for generating descriptors, including Speed Up Robust Features (SURF), Gradient Location and Orientation Histogram (GLOH), Local Energy based Shape Histogram (LESH), among others, may also benefit for the features described herein.

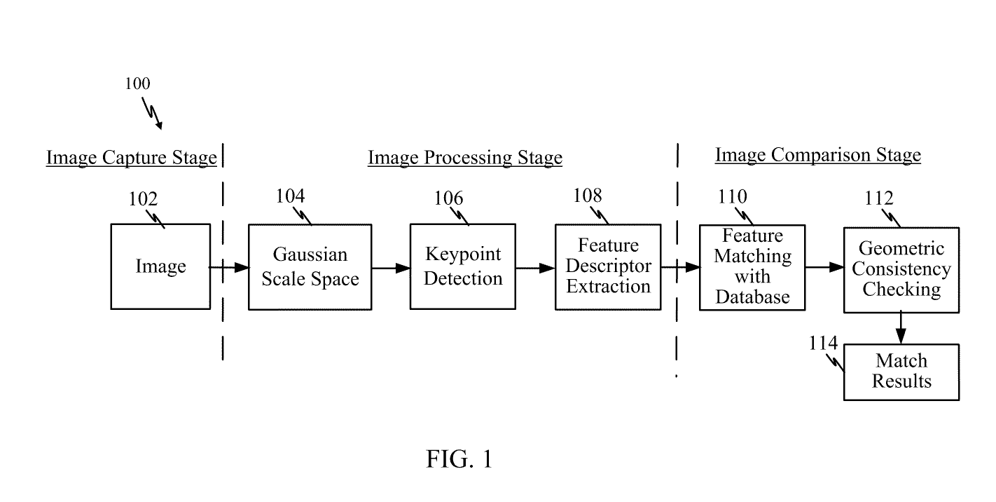

FIG. 1 is a block diagram illustrating the functional stages for performing object recognition on a queried image. At an image capture stage, an image 102 of interest may be captured. The captured image 102 is then processed by generating a corresponding Gaussian scale space 104, performing keypoint detection 106, and performing feature descriptor extraction 108. At the end of the image processing stage, a plurality of descriptors (e.g., feature descriptors) have been generated that identify one or more objects or features within the captured image 102. At an image comparison stage, these descriptors are used to perform feature matching 110 (e.g., by comparing keypoints and/or other characteristics) with a database of known descriptors. Geometric consistency checking 112 is then performed on keypoint matches to ascertain correct feature matches and provide match results 114.

Image Capturing: In one example, the image 102 may be captured in a digital format that may define the image I(x, y) as a plurality of pixels with corresponding color, illumination, and/or other characteristics.

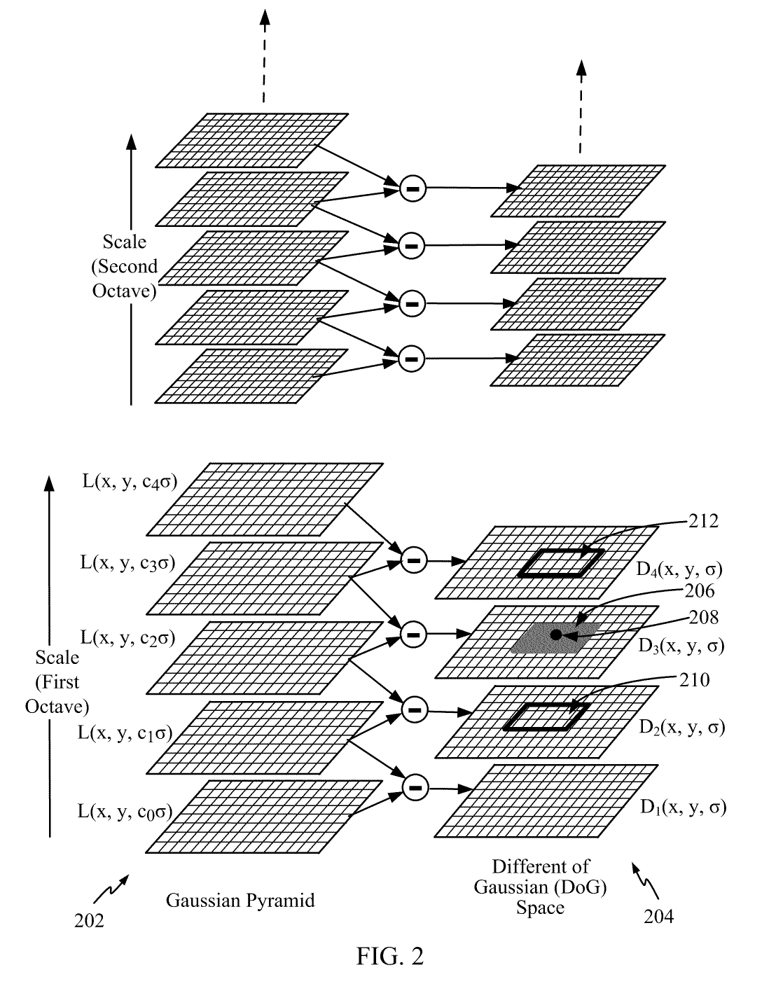

Gaussian Scale Space: FIG. 2 illustrates a difference of Gaussian (DoG) pyramid 204 constructed by computing the difference of any two consecutive Gaussian-blurred images in the Gaussian pyramid 202. The input image I(x, y) is gradually Gaussian blurred to construct the Gaussian pyramid 202. Gaussian blurring generally involves convolving the original image I(x, y) with the Gaussian blur function G(x, y, cσ) at scale cσ such that the Gaussian blurred function L(x, y, cσ) is defined as L(x, y, cσ)=G(x, y, cσ)*I(x, y). Here, G is a Gaussian kernel, cσ denotes the standard deviation of the Gaussian function that is used for blurring the image I(x, y). As c, is varied (c₀<c₁<c₂<c₃<c₄), the standard deviation cσ varies and a gradual blurring is obtained. Sigma σ is the base scale variable (essentially the width of the Gaussian kernel). When the initial image I(x, y) is incrementally convolved with Gaussians G to produce the blurred images L, the blurred images L are separated by the constant factor c in the scale space.

In the DoG space 204, D(x, y, a)=L(x, y, cₙσ)−L(x, y, cₙ₋₁σ). A DoG image D(x, y, σ) is the difference between two adjacent Gaussian blurred images L at scales cₙσ and cₙ₋₁σ. The scale of the D(x, y, σ) lies somewhere between cₙσ and cₙ₋₁σ. As the number of Gaussian-blurred images L increase and the approximation provided for the Gaussian pyramid 202 approaches a continuous space, the two scales also approach into one scale. The convolved images L may be grouped by octave, where an octave corresponds to a doubling of the value of the standard deviation σ. Moreover, the values of the multipliers k (e.g., c₀<c₁<c₂<c₃<c₄), are selected such that a fixed number of convolved images L are obtained per octave. Then, the DoG images D may be obtained from adjacent Gaussian-blurred images L per octave. After each octave, the Gaussian image is down-sampled by a factor of 2 and then the process is repeated.

Keypoint Detection: The DoG space 204 may then be used to identify keypoints for the image I(x, y). Keypoint detection seeks to determine whether the local region or patch around a particular sample point or pixel in the image is a potentially interesting patch (geometrically speaking). Generally, local maxima and/or local minima in the DoG space 204 are identified and the locations of these maxima and minima are used as keypoint locations in the DoG space 204. In the example illustrated in FIG. 2, a keypoint 208 has been identified with a patch 206. Finding the local maxima and minima (also known as local extrema detection) may be achieved by comparing each pixel (e.g., the pixel for keypoint 208) in the DoG space 204 to its eight neighboring pixels at the same scale and to the nine neighboring pixels (in adjacent patches 210 and 212) in each of the neighboring scales on the two sides, for a total of 26 pixels (9×2+8=26). If the pixel value for the keypoint 206 is a maximum or a minimum among all 26 compared pixels in the patches 206, 210, and 208, then it is selected as a keypoint. The keypoints may be further processed such that their location is identified more accurately and some of the keypoints, such as the low contrast key points and edge key points may be discarded.

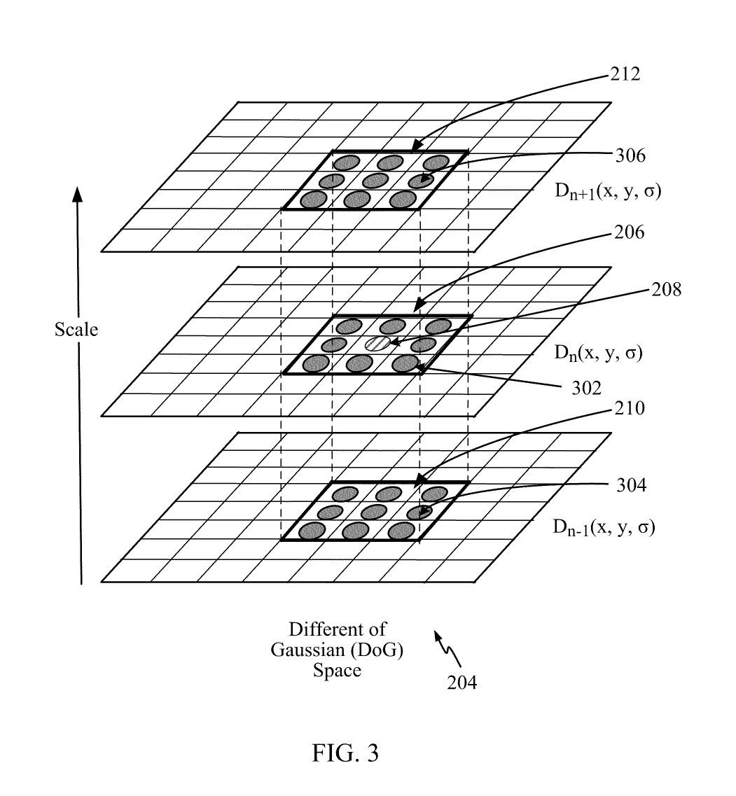

FIG. 3 illustrates a more detailed view of how a keypoint may be detected. Here, each of the patches 206, 210, and 212 include a 3×3 pixel region. A pixel of interest (e.g., keypoint 208) is compared to its eight neighboring pixels 302 at the same scale (e.g., patch 206) and to the nine neighboring pixels 304 and 306 in adjacent patches 210 and 212 in each of the neighboring scales on the two sides of the keypoint 208.

Descriptor Extraction: Each keypoint may be assigned one or more orientations, or directions, based on the directions of the local image gradient. By assigning a consistent orientation to each keypoint based on local image properties, the keypoint descriptor can be represented relative to this orientation and therefore achieve invariance to image rotation. Magnitude and direction calculations may be performed for every pixel in the neighboring region around the keypoint 208 in the Gaussian-blurred image L and/or at the keypoint scale. The magnitude of the gradient for the keypoint 208 located at (x, y) may be represented as m(x, y) and the orientation or direction of the gradient for the keypoint at (x, y) may be represented as Γ(x, y). The scale of the keypoint is used to select the Gaussian smoothed image, L, with the closest scale to the scale of the keypoint 208, so that all computations are performed in a scale-invariant manner. For each image sample, L(x, y), at this scale, the gradient magnitude, m(x, y), and orientation, Γ(x, y), are computed using pixel differences. For example the magnitude m(x,y) may be computed as:

$$m ( x , y ) = \sqrt{\begin{matrix}{( L ( x + 1 , y ) - L ( x - 1 , y ) )}^{2} + \\ {( L ( x , y + 1 ) - L ( x , y - 1 ) )}^{2}\end{matrix}} . \qquad ( Equation 1 )$$

The direction or orientation Γ(x, y) may be calculated as:

$$Γ ( x , y ) = arctan [ \frac{( L ( x , y + 1 ) L ( x , y - 1 )}{( L ( x + 1 , y ) - L ( x - 1 , y )} ] . \qquad ( Equation 2 )$$

Here, L(x, y) is a sample of the Gaussian-blurred image L(x, y, σ), at scale σ which is also the scale of the keypoint.

The gradients for the keypoint may be calculated consistently either for the plane in the Gaussian pyramid that lies above, at a higher scale, than the plane of the keypoint in the DoG space or in a plane of the Gaussian pyramid that lies below, at a lower scale, than the keypoint. Either way, for each keypoint, the gradients are calculated all at one same scale in a rectangular area (e.g., patch) surrounding the keypoint. Moreover, the frequency of an image signal is reflected in the scale of the Gaussian-blurred image. Yet, SIFT simply uses gradient values at all pixels in the patch (e.g., rectangular area). A patch is defined around the keypoint; sub-blocks are defined within the block; samples are defined within the sub-blocks and this structure remains the same for all keypoints even when the scales of the keypoints are different. Therefore, while the frequency of an image signal changes with successive application of Gaussian smoothing filters in the same octave, the keypoints identified at different scales may be sampled with the same number of samples irrespective of the change in the frequency of the image signal, which is represented by the scale.

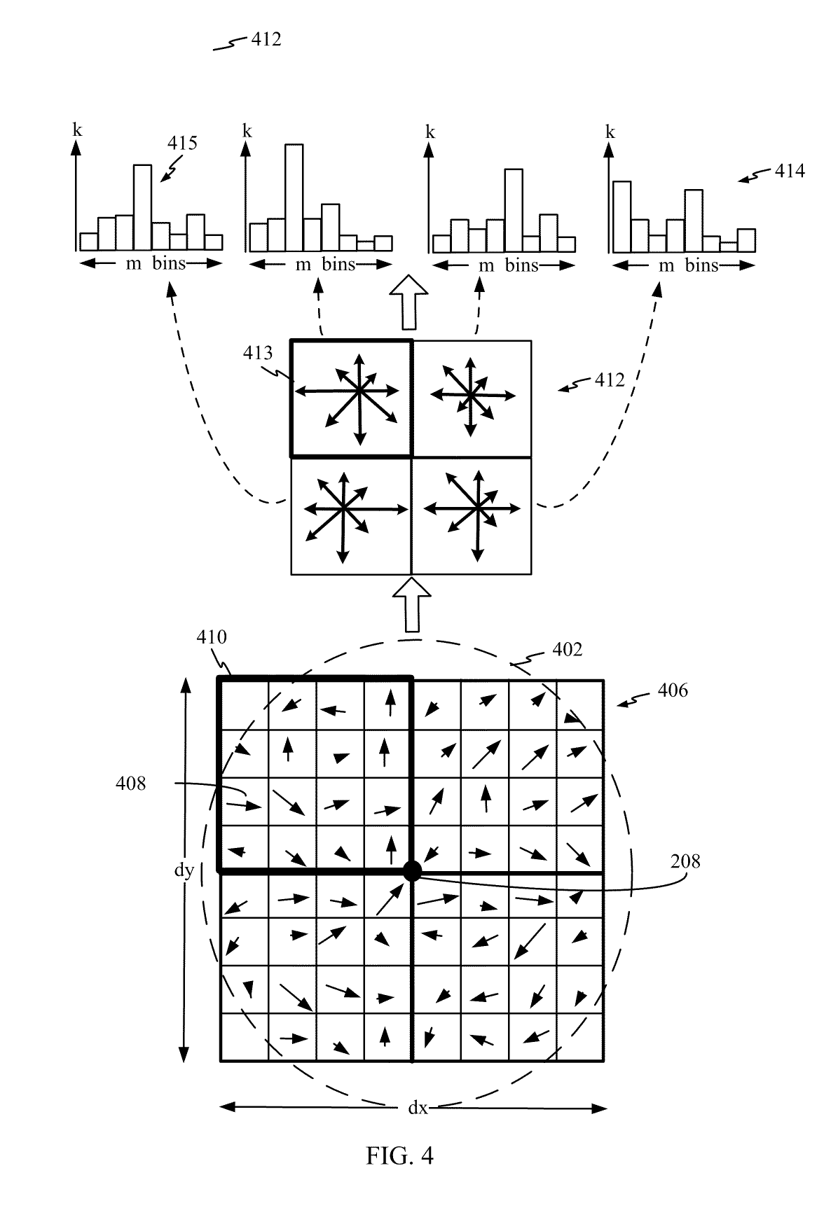

To characterize a keypoint orientation, a vector of gradient orientations may be generated (in SIFT) in the neighborhood of the keypoint (using the Gaussian image at the closest scale to the keypoint's scale). However, keypoint orientation may also be represented by a gradient orientation histogram (see FIG. 4) by using, for example, Compressed Histogram of Gradients (CHoG). The contribution of each neighboring pixel may be weighted by the gradient magnitude and a Gaussian window. Peaks in the histogram correspond to dominant orientations. All the properties of the keypoint may be measured relative to the keypoint orientation, this provides invariance to rotation.

In one example, the distribution of the Gaussian-weighted gradients may be computed for each block where each block is 2 sub-blocks by 2 sub-blocks for a total of 4 sub-blocks. To compute the distribution of the Gaussian-weighted gradients, an orientation histogram with several bins is formed with each bin covering a part of the area around the keypoint. For example, the orientation histogram may have 36 bins, each bin covering 10 degrees of the 360 degree range of orientations. Alternatively, the histogram may have 8 bins each covering 45 degrees of the 360 degree range. It should be clear that the histogram coding techniques described herein may be applicable to histograms of any number of bins. Note that other techniques may also be used that ultimately generate a histogram.

FIG. 4 illustrates how a gradient distributions and orientation histograms may be obtained. Here, a two-dimensional gradient distribution (dx, dy) (e.g., block 406) is converted to a one-dimensional distribution (e.g., histogram 414). The keypoint 208 is located at a center of the patch 406 (also called a cell or region) that surrounds the keypoint 208. The gradients that are pre-computed for each level of the pyramid are shown as small arrows at each sample location 408. As shown, 4×4 regions of samples 408 form a sub-block 410 and 2×2 regions of sub-blocks form the block 406. The block 406 may also be referred to as a descriptor window. The Gaussian weighting function is shown with the circle 402 and is used to assign a weight to the magnitude of each sample point 408. The weight in the circular window 402 falls off smoothly. The purpose of the Gaussian window 402 is to avoid sudden changes in the descriptor with small changes in position of the window and to give less emphasis to gradients that are far from the center of the descriptor. A 2×2=4 array of orientation histograms 412 is obtained from the 2×2 sub-blocks with 8 orientations in each bin of the histogram resulting in a (2×2)×8=32 dimensional feature descriptor vector. For example, orientation histograms 413 and 415 may correspond to the gradient distribution for sub-block 410. However, using a 4×4 array of histograms with 8 orientations in each histogram (8-bin histograms), resulting in a (4×4)×8=128 dimensional feature descriptor vector for each keypoint may yield a better result. Note that other types of quantization bin constellations (e.g., with different Voronoi cell structures) may also be used to obtain gradient distributions.

As used herein, a histogram is a mapping kᵢ that counts the number of observations, sample, or occurrences (e.g., gradients) that fall into various disjoint categories known as bins. The graph of a histogram is merely one way to represent a histogram. Thus, if k is the total number of observations, samples, or occurrences and m is the total number of bins, the frequencies in histogram kᵢ satisfy the following condition:

$$n = {\sum }_{i = 1}^{m} {k}_{i} , \qquad ( Equation 3 )$$

where Σ is the summation operator.

Each sample added to the histograms 412 may be weighted by its gradient magnitude within a Gaussian-weighted circular window 402 with a standard deviation that is 1.5 times the scale of the keypoint. Peaks in the resulting orientation histogram 414 correspond to dominant directions of local gradients. The highest peak in the histogram is detected and then any other local peak that is within a certain percentage, such as 80%, of the highest peak is used to also create a keypoint with that orientation. Therefore, for locations with multiple peaks of similar magnitude, there will be multiple keypoints created at the same location and scale but different orientations.

The histograms from the sub-blocks may be concatenated to obtain a feature descriptor vector for the keypoint. If the gradients in 8-bin histograms from 16 sub-blocks are used, a 128 dimensional feature descriptor vector may result.

In this manner a descriptor may be obtained for each keypoint, where such descriptor may be characterized by a location (x, y), an orientation, and a descriptor of the distributions of the Gaussian-weighted gradients. Note that an image may be characterized by one or more keypoint descriptors (also referred to as image descriptors).

In some exemplary applications, an image may be obtained and/or captured by a mobile device and object recognition may be performed on the captured image or part of the captured image. According to a first option, the captured image may be sent by the mobile device to a server where it may be processed (e.g., to obtain one or more descriptors) and/or compared to a plurality of images (e.g., one or more descriptors for the plurality of images) to obtain a match (e.g., identification of the captured image or object therein). However, in this option the whole captured image is sent, which may be undesirable due to its size. In a second option, the mobile device processes the image (e.g., perform feature extraction on the image) to obtain one or more image descriptors and sends the descriptors to a server for image and/or object identification. Because the keypoint descriptors for the image are sent, rather than the image, this may take less transmission time so long as the keypoint descriptors for the image are smaller than the image itself. Thus, compressing the size of the keypoint descriptors is highly desirable.

In order to minimize the size of a keypoint descriptor, it may beneficial to compress the descriptor of the distribution of gradients. Since the descriptor of the distribution of gradients is represented by histogram, efficient coding techniques for histograms are described herein.

### Efficient Coding of Histograms

In order to efficiently represent and/or compress feature descriptors, the descriptor of the distributions (e.g., orientation histograms) may be more efficiently represented. Thus, one or more methods or techniques for efficiently coding of histograms are herein provided. Note that these methods or techniques may be implemented with any type of histogram implementation to efficiently (or even optimally) code a histogram in a compressed form. Efficiently coding of a histogram is a distinct problem not addressed by traditional encoding techniques. Traditional encoding techniques have focused on efficiently encoding a sequence of values. Because sequence information is not used in a histogram, efficiently encoding a histogram is a different problem.

As a first step, consideration is given to the optimal (smallest size or length) coding of a histogram. Information theory may be applied to obtain a maximum length for lossless and/or lossy encoding of a histogram.

As noted above, for a particular patch (e.g., often referred to as a cell or region), the distribution of gradients in the patch may be represented as a histogram. A histogram may be represented as an alphabet A having a length of m symbols (2≦m≦∞), where each symbol is associated with a bin in the histogram. Therefore, the histogram has a total number of m bins. For example, each symbol (bin) in the alphabet A may correspond to a gradient/orientation from a set of defined gradients/orientations. Here, n may represent the total number of observations, samples, or occurrences (gradient samples in a cell, patch, or region) and k represents the number of observations, samples, or occurrences in a particular bin (e.g., k₁ is number of gradient samples in the first bin, and kₘ is the number of gradient samples in the m-th bin), such that n=Σ_{i=1 . . . m}kᵢ. That is, the sum of all gradient samples in the histogram bins is equal to the total number of gradient samples in the patch. Because a histogram may represent a probability distribution for a first distribution of gradient samples within a cell, patch, or region, it is possible that different cells, patches, or regions having a second distribution (different from the first distribution) of gradient samples may nonetheless have the same histogram.

Let now P denote an m-ary probability distribution. [p₁, . . . , pₘ]. The entropy H(P) of this distribution defined as:

$$H ( P ) = - {\sum }_{i = 1}^{m} {p}_{i} log {p}_{i} . \qquad ( Equation 4 )$$

The relative entropy D(P∥Q) between two known distributions P and Q is given by

$$D ( P ‖ Q ) = {\sum }_{i = 1}^{m} {p}_{i} log \frac{{p}_{i}}{{q}_{i}} . \qquad ( Equation 5 )$$

For a given sample w of gradient distributions, lets assume that the number of times each gradient value appears is given by kᵢ (for i=1, . . . m). The probability P(w) of the sample w is thus given by:

$$P ( w ) = {\prod }_{i = 1}^{m} {p}_{i} {k}^{{k}_{i}} \qquad ( Equation 6 )$$

where Π is the product operator.
For example, in the case of a cell or patch, the probability P(w) is going to be a probability of a particular cell or patch.

However, Equation 6 assumes that the distribution P is known. In the case where the source distribution is unknown, as may be the case with typical gradients in a patch, the probability of a sample w may be given by the Krichevsky-Trofimov (KT) estimate:

$${P}_{KT} ( w ) = Γ ( \frac{m}{2} ) \frac{{\prod }_{i = 1}^{m} Γ ( {k}_{i} + \frac{1}{2} )}{{π}^{\frac{m}{2}} Γ ( n + \frac{m}{2} )} , \qquad ( Equation 7 )$$

where Γ is the Gamma function such that Γ(n)=(n−1)!.

If the sample w is to be encoded using the KT-estimate of its probability, the length L of such encoding (under actual distribution P) satisfies:

$${L}_{KT} ( w , P ) = - {\sum }_{w} P ( m ) log {P}_{KT} ( w ) \sim nH ( P ) + \frac{m - 1}{2} log n . \qquad ( Equation 8 )$$

Equation 8 provides the maximum code length for lossless encoding of a histogram. The redundancy of KT-estimator-based code is given by:

$${R}_{KT} ( n ) \sim \frac{m - 1}{2} log n , \qquad ( Equation 9 )$$

which does not depend on the actual source distribution. This implies that such code is universal. Thus, the KT-estimator provides a close approximation of actual probability P so long as the sample w used is sufficiently long.

Note that the KT-estimator is only one way to compute probabilities for distributions. For example, a maximum likelihood (ML) estimator may also be used.

Also, when coding a histogram, it is assumed that both the encoder and decoder know the total number of samples n in the histogram and the number of bins m for the histogram. Thus, this information need not be encoded. Therefore, the encoding is focused on the number of samples for each of the m bins.

Coding of Types: Rather than transmitting the histogram itself as part of the keypoint (or image) descriptor, a compressed form of the histogram may be used. To accomplish this, histograms may be represented by types. Generally, a type is a compressed representation of a histogram (e.g., where the type represents the shape of the histogram rather than full histogram). The type t of a sample w may be defined as:

$$t ( w ) = [ \frac{{k}_{1}}{n} , … , \frac{{k}_{n}}{n} ] \qquad ( Equation 10 )$$

such that the type t(w) represents a set of frequencies of its symbols (e.g., the frequencies of gradient distributions kᵢ). A type can also be understood as an estimate of the true distribution of the source that produced the sample. Thus, encoding and transmission of type t(w) is equivalent to encoding and transmission of the shape of the distribution as it can be estimated based on a particular sample w.

However, traditionally encoding techniques have focused on efficiently encoding a sequence of values. Because sequence information is not used in a histogram, efficiently encoding a histogram is a different problem. Assuming the number of bins is known to the encoder and decoder, encoding of histograms involves encoding the total number of points (e.g., gradients) and the points per bin.

Sample-to-Type Mapping: Hereafter, the goal is to figure out how to encode type t(w) efficiently. Notice that any given type t may be defined as:

$$t = [ \frac{{k}_{1}}{n} , … , \frac{{k}_{n}}{n} \text{:} { \sum }_{i = 1}^{m} {k}_{i} = n ] . \qquad ( Equation 11 )$$

where k₁ to kₘ denote the number of possible types t given the total number of samples n.
Therefore, the total number of possible sequences with type t can be given by:

$$ξ ( t ) = ( \begin{matrix}n \\ {k}_{1} , … , {k}_{m}\end{matrix} ) \qquad ( Equation 12 )$$

where ξ(t) is total number of possible arrangements of symbols with a population t.

The total number of possible types is essentially the number of all integers k₁, . . . , kₘ such that k₁+ . . . +kₘ=n, and it is given by the multiset coefficient:

$$M ( m , n ) = ( \begin{matrix}n + m - 1 \\ m - 1\end{matrix} ) \qquad ( Equation 13 )$$

Distribution of Types: The probability of occurrence of any sample w of type t may be denoted by P(t). Since there are ξ(t) such possible samples, and they all have the same probabilities, then:

$$\begin{matrix}P ( t ) = ξ ( t ) P ( w \text{:} t ( w ) = t ) \\ = ( \begin{matrix}n \\ {k}_{1} , … , {k}_{m}\end{matrix} ) {p}_{1}^{{k}_{1}} … {p}_{m}^{{k}_{m}}\end{matrix} \qquad ( Equation 14 )$$

This density P(t) may be referred to as a distribution of types. It is clearly a multinomial distribution, with maximum (mode) at:

P(t*)=P(t:kᵢ=npᵢ)=(ₙₚ_{₁}_{, . . . , np}_{ₘ}ⁿ)p₁^{np}^{₁} . . . pₘ^{np}^{_{m.}} (Equation 15)

The entropy of distribution of types is subsequently (by concentration property):

$$\begin{matrix}H ( P ( t ) ) = - {\sum }_{t} P ( t ) log P ( t ) \sim log ( P ( {t}^{*} ) ) \\ = \frac{m - 1}{2} log n + O ( 1 ) .\end{matrix} \qquad ( Equation 16 )$$

Universal Coding and Lossless Coding of Types: Given a sample w of length n, the task of universal encoder is to design a code f(w) (or equivalently, its induced distribution P_{f}(w)), such that its worst-case average redundancy:

$$\begin{matrix}{R}^{*} ( n ) = {sup}_{P} [ {\sum }_{\vert w \vert = n} P ( w ) \vert f ( w ) \vert - nH ( P ) ] & ( Equation 17 ) \\ \geq {sup}_{P} {\sum }_{\vert w \vert = n} P ( w ) log \frac{P ( w )}{{P}_{f} ( w )} = n {sup}_{P} D ( P ‖ {P}_{f} ) & ( Equation 18 )\end{matrix}$$

is minimal Equations 17 and 18 describe the problem being addressed by universal coding, which given a sequence, a code length is sought where the difference between an average code length and n*H(P) is minimal for all possible input distributions. That is, the minimum worst-case code length is sought without knowing the distribution beforehand.

Since probabilities of samples of the same type are the same, and code induced distribution P_{f}(w) is expected to retain this property, P_{f}(w) can be defined as:

$${P}_{f} ( w ) = \frac{{P}_{f} ( w \text{:} t ( w ) = t )}{ξ ( t )} , \qquad ( Equation 19 )$$

where P_{f}(t) is the probability of a type t(w) and ξ(t) is the total number of sequences within the same type t(w). The probability P_{f} of a code assigned to a type t(w) can thus be defined as:

P_{f}(t)=ξ(t)P_{f}(w:t(w)=t) (Equation 20)

is code-induced distribution of types.

By plugging such decomposition in Equation 18 and changing the summation to go over types (instead of individual samples), the average redundancy R*(n) may be defined as:

$$\begin{matrix}{R}^{*} ( n ) \geq {sup}_{P} {\sum }_{\vert w ∈ {A}^{n}} P ( w ) log \frac{P ( w )}{{P}_{f} ( w )} & ( Equation 21.1 ) \\ = {sup}_{P} [ {\sum }_{t} {\sum }_{w : t ( w ) = t} P ( w ) log \frac{P ( t )}{{P}_{f} ( t )} ] & ( Equation 21.2 ) \\ = {sup}_{p} [ {\sum }_{t} P ( t ) log \frac{P ( t )}{{P}_{f} ( t )} ] & ( Equation 21.3 ) \\ = {sup }_{P} D ( P ( t ) ‖ {P}_{f} ( t ) ) , & ( Equation 21.4 )\end{matrix}$$

where “sup” is the supremum operator, where a value is a supremum with respect to a set if it is at least as large as any element of that set. These equations mean that the problem of coding of types is equivalent to the problem of minimum redundancy universal coding.

Consequently, the problem of lossless coding of types can be asymptotically optimally solved by using KT-estimated distribution of types:

$$\begin{matrix}{P}_{KT} ( t ) = ξ ( t ) {P}_{KT} ( w : t ( w ) = t ) & ( Equation 22.1 ) \\ = ( \begin{matrix}n \\ {k}_{1} , … , {k}_{m}\end{matrix} ) Γ ( \frac{m}{2} ) \frac{{\prod }_{i = 1}^{m} Γ ( {k}_{i} + \frac{1}{2} )}{{π}^{\frac{m}{2}} Γ ( n + \frac{m}{2} )} & ( Equation 22.2 )\end{matrix}$$

Based on this Equation 22.2, it becomes clear that types with near uniform populations fall in the valleys of the estimated density, while types with singular populations (ones with zero counts) become its peaks.

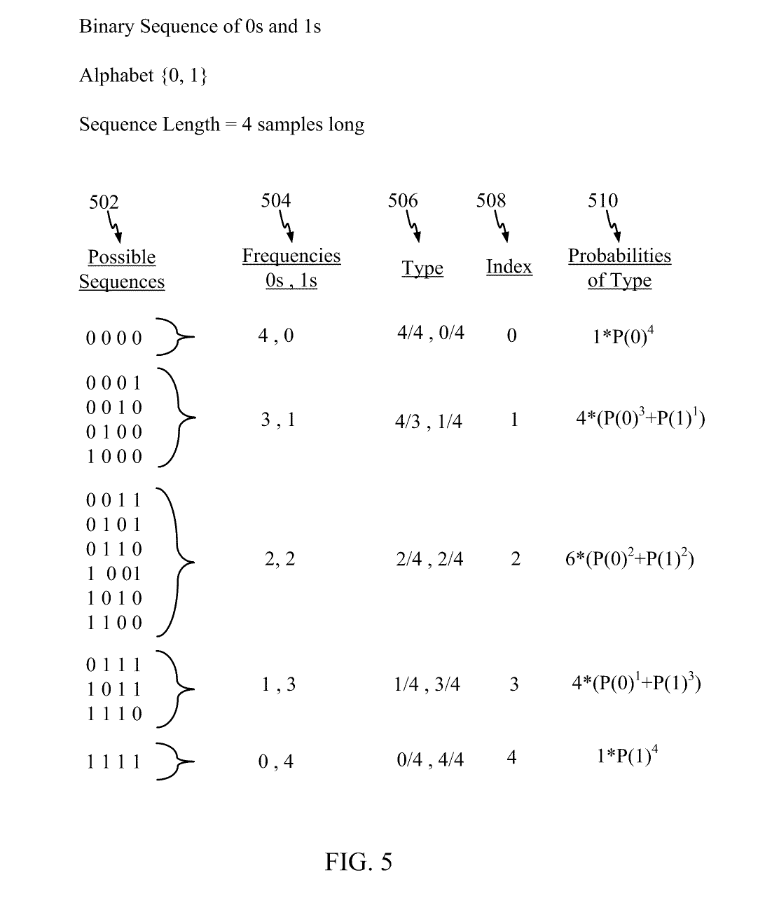

FIG. 5 illustrates one example for the construction and selection of types and indexes. In this example, sample sequence has a length of four samples (n=4), with two possible symbols (m=2) (e.g., alphabet of symbols 0 and 1). All possible sequences 502 have been arranged herein showing their distributions 504 for the two symbols (0, 1). From this distribution 504, it can be seen that each distribution 504 may be assigned a Type 506 so that the possible sequences 502 can be represented by five (5) types. Note that each type may represent a histogram. Each Type 506 may be assigned an Index 508, which may be used for transmission or storage of a histogram. Note that the sum of the Probability of Type 510 will be equal to 1.

Design of Codes: Since size of type distribution

$$M ( m , n ) = ( \begin{matrix}n + m - 1 \\ m - 1\end{matrix} ) \qquad ( Equation 23 )$$

is known, and which probabilities to assign to each type (Equation 22.2), the remaining problem is designing a Huffman code for that distribution.

In order to encode a type with parameters k₁, . . . , kₘ, a unique index I(kᵢ, . . . , kₘ) may be obtained. The index I may be computed as follows:

$$I ( {k}_{1} , … , {k}_{m} ) = {\sum }_{j = 1}^{n - 2} {\sum }_{i = 0}^{{k}_{j} - 1} ( \begin{matrix}n - 1 - {\sum }_{l = 1}^{j - 1} {k}_{l} + m - j - 1 \\ m - j - 1\end{matrix} ) + {k}_{n - 1} . \qquad ( Equation 24 )$$

Equation 24 follows by induction (starting with m=2, 3, . . . ) and implements a lexicographic enumeration of types. For example,

$$\begin{matrix}I ( 0 , 0 , … , 0 , n ) = 0 , \\ I ( 0 , 0 , … , 1 , n - 1 ) = 1 , \\ … . \\ I ( n , 0 , … , 0 , 0 ) = ( \begin{matrix}n + m - 1 \\ m - 1\end{matrix} ) - 1.\end{matrix}$$

With a pre-computed array of binomial coefficients, the computation of the index I by suing Equation 24 requires O(n) operations.

Type Encoding Rate: The type encoding rate refers to how efficiently a type may be encoded. From Equations 8, 9, and 16, and the above discussion, it can be ascertained that the rate of code for KT-estimated density for types (Equation 22) satisfies (under any actual distribution P):

$$\begin{matrix}L ( t , n ) = H ( t ) + {R}_{KT} ( n ) \\ \sim H ( t ) + \frac{m - 1}{2} log n + O ( 1 ) .\end{matrix} \qquad ( Equation 25 )$$

where H(t) is the entropy of type distribution. By expanding Equation 25 using Equation 16, the rate (or length) of code obtained is:

L(t,n)=(m−1)log n+O(1). (Equation 26)

Encoding Precision versus Rate: Based on the above observations and Equation 28, it is noted that coding of type gives an exact rate, which is proportional to the logarithm of length of the sample.

In some cases, however, it may be required to fit distribution description into a smaller number of bits. Therefore, there is a need for a mechanism for quantizing type information.

Perhaps the simplest way to accomplish this is to simply replace sample type:

$$t = [ \frac{{k}_{1}}{n} , … , \frac{{k}_{m}}{n} : {\sum }_{i} {k}_{i} = n ] \qquad ( Equation 27 )$$

with modified quantities:

$$\tilde{t} = [ \frac{{\tilde{k}}_{1}}{\tilde{n}} , … , \frac{{\tilde{k}}_{m}}{\tilde{n}} : {\sum }_{i} {\tilde{k}}_{i} = \tilde{n} ] , \qquad ( Equation 28 )$$

and with a smaller new total ñ<n. This new total ñ can be given as an input parameter, and so the task is to find quantities \tilde{k}ᵢ, such that:

$$\frac{{\tilde{k}}_{i}}{\tilde{n}} \approx \frac{{k}_{i}}{n} . \qquad ( Equation 29 )$$

### Therefore,

$${\tilde{k}}_{i} \approx {k}_{i} \frac{\tilde{n}}{n} . \qquad ( Equation 30 )$$

The whole problem can be viewed as one of scalar quantization with step size ñ/n and an extra constraint that Σ\tilde{k}ᵢ=ñ.

Type Quantization: The task of type quantizing can be solved, for example, by the following modification of Conway and Sloane's algorithm (discussed by J. H. Conway and N.J. A. Sloane, “Fast Quantizing and Decoding Algorithms for Lattice Quantizers and Codes”, IEEE Transactions on Information Theory, Vol. IT-28, No. 2, (1982)). According to one example, a set of types may be quantized according to the following algorithm.

1. Given quantities {kᵢ}, produce best unconstrained approximations:

$${\hat{k}}_{i} = ⌊ {k}_{i} \frac{\tilde{n}}{n} + \frac{1}{2} ⌋ .$$

2. Compute quantity:

$$d = {\sum }_{i} {\hat{k}}_{i} - \tilde{n}$$

a. if d=0 go to step 5.

3. Compute approximation errors:

$${δ}_{i} = {\hat{k}}_{i} - {k}_{i} \frac{\tilde{n}}{n} ,$$

and sort them such that:

$$- \frac{1}{2} \leq {δ}_{{i}_{1}} \leq {δ}_{{i}_{2}} \leq … \leq {δ}_{{i}_{m}} \leq \frac{1}{2} .$$

4. If d>0 then decrement d values \hat{k}ᵢ_{ⱼ} with largest errors:

\hat{k}ᵢ_{ⱼ}=\hat{k}ᵢ_{ⱼ}−1,j=m−d . . . m;

otherwise (when d<0) then increment d values \hat{k}ᵢ_{ⱼ} with smallest errors:

\hat{k}ᵢ_{ⱼ}=\hat{k}ᵢ_{ⱼ}+1,i=1 . . . d.

5. Save the adjusted values as best found approximations: \tilde{k}ᵢ=\hat{k}ᵢ, i=1 . . . m;

\tilde{k}ᵢ=\hat{k}ᵢ,i=1 . . . m.

The precision of approximations found by this algorithm satisfies:

$${δ}^{*} ( \frac{\tilde{k}}{\tilde{n}} , \frac{k}{n} ) = {max}_{i} \vert \frac{{\tilde{k}}_{i}}{\tilde{n}} - \frac{{k}_{i}}{n} \vert \leq \frac{1}{\tilde{n}} ; \qquad ( Equation 31 )$$

and

$$V ( \frac{\tilde{k}}{\tilde{n}} , \frac{k}{n} ) = {\sum }_{1} \vert \frac{{\tilde{k}}_{i}}{\tilde{n}} - \frac{{k}_{i}}{n} \vert \leq \frac{m}{2 \tilde{n}} . \qquad ( Equation 32 )$$

Based on the above discussion, it is known that the rate needed to encode a type with quantized total ñ will be:

R(t,ñ)≦(m−1)log ñ+O(1). (Equation 33)

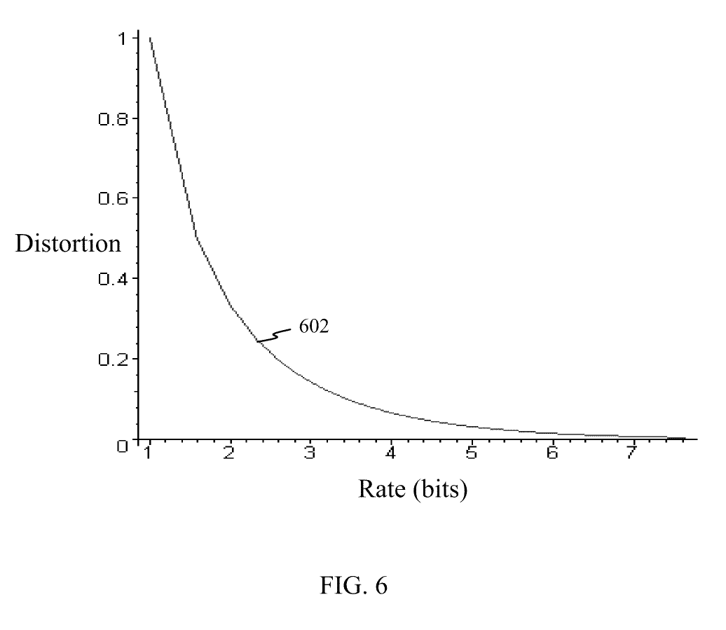

The upper bounds for both rate and distortion may be given by, for example, parametric functions of ñ. FIG. 6 illustrates a plot of a Rate versus Distortion (R-D) boundary 602 achievable by type coding (for m=2).

It can be readily shown that an approximate direct form expression for this curve is

$${δ}^{*} ( \frac{\tilde{k}}{\tilde{n}} , \frac{k}{n} ) \leq {2}^{- \frac{R}{m - 1}} . \qquad ( Equation 34 )$$

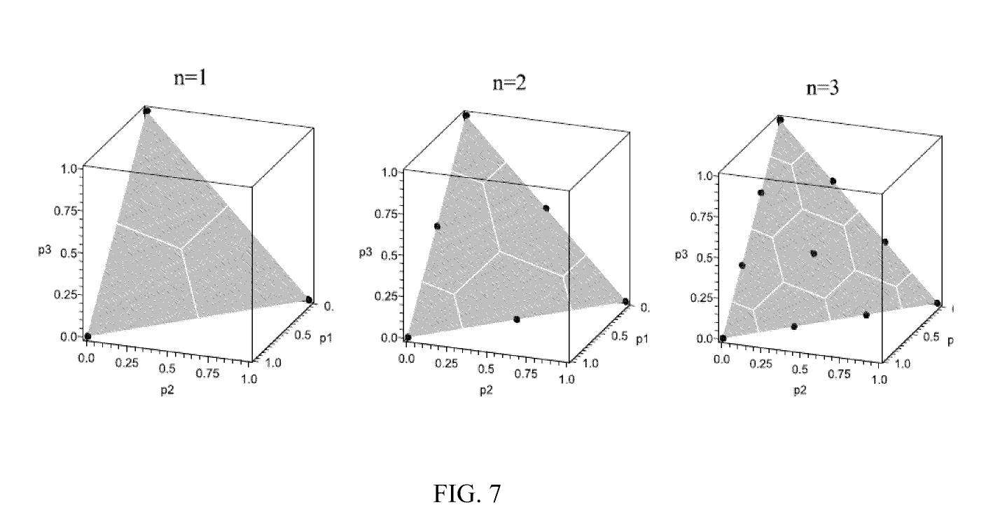

It should be noted that the quantized types essentially create a lattice over a probability space. Even very small values of parameter n (or ñ) are sufficient to fully cover it. FIG. 7 illustrate several example type lattices created for ternary histograms (e.g., Voronoi partitions for m=3 and n=1, 2, 3).

The one or more techniques, algorithms, and/or features described herein may serve to optimally encode estimated shapes of distributions. These one or more techniques may be applied to coding of distributions of keypoint descriptors, such as SIFT, SURF, GLOH, CHoG and others.

### Exemplary Histogram Encoder

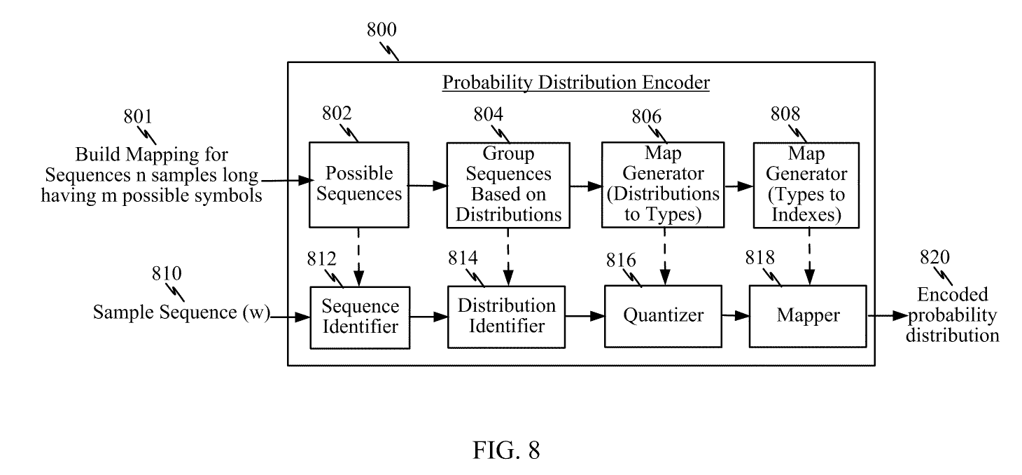

FIG. 8 is a block diagram illustrating an example of a probability distribution encoder 800. The probability distribution encoder may be an independent circuit, processor, or module or it may be integrated into another circuit, processor, or module. The probability distribution encoder 800 may initially build or obtain a mapping of sequences n samples long, the sequence having m possible symbols 801. First, all possible sequences 802 (n samples long composed of m possible symbols) are generated. Then, these sequences may be grouped based on their distributions 804. That is, sequences having the same distributions are grouped together. Then, the different distributions are mapped to a set of types 806. The types may be further mapped to an index 808. Note that a corresponding decoder may have corresponding index-to-type and type-to-distribution mappings. These mappings 806 and 808 may be done beforehand (in advance of receipt of actual sample sequences) or may be dynamically generated using a actual sample sequences.

Upon receipt of a sample sequence (w) 810, the probability distribution encoder 800 may use a sequence identifier 812 to identify the sequence. A distribution identifier 814 may then identify the probability distribution for the identified sequence. A quantizer 816 may then quantize the probability distribution into a type for such probability distribution. A mapper 818 may then map the type to an index that is transmitted to represent an encoded probability distribution 820 of the sample sequence 810.

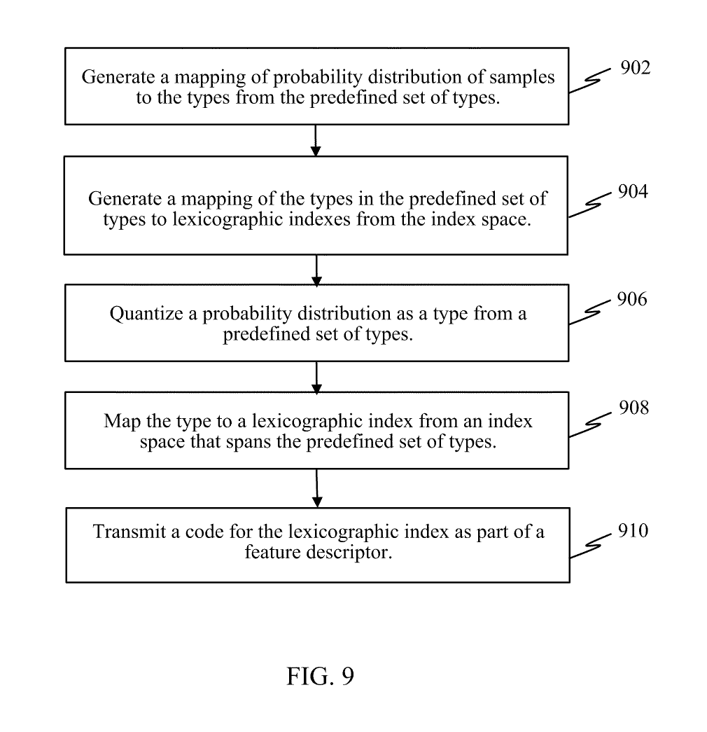

FIG. 9 illustrates a method for efficiently encoding probability distributions. A mapping of probability distributions of samples to types from a predefined set of types may be generated or obtained 902. A mapping of the types in the predefined set of types to lexicographic indexes from an index space is then generated or obtained 904. Subsequently, a probability distribution may be obtained. In one example, the probability distribution may be given by a histogram. The obtained probability distribution is quantized as a type from the predefined set of types 906. The type is then mapped to a lexicographic index from the index space that spans the predefined set of types 908. A code for the lexicographic index is then transmitted (or stored) as part of a feature descriptor 910. The set of types may be given by a set of rational numbers

$$\{ \frac{{k}_{1}}{n} , … , \frac{{k}_{m}}{n} \} ,$$

where n is a fixed positive integer, and where k₁, . . . , kₘ are non-negative integers, such that

$${\sum }_{i = 1}^{m} {k}_{i} = n ,$$

and where m is the number of dimensions in the probability distribution. The set of types may contain M(m, n) possible types, where

$$M ( m , n ) = ( \begin{matrix}n + m - 1 \\ m - 1\end{matrix} ) ,$$

where n is the common parameter of types and m is the number of dimensions in the probability distribution.

In one example, the code may be a fixed-length code presented as a binary representation of the lexicographic index of the type. In another example, the code may be a variable-length code corresponding to a lexicographic index of the type. The code may be a variable length code based on an estimated universal probability assignment to each type. For instance, the estimated universal probability assignment to each type may be given by

$${P}_{KT} ( t ) = ( \begin{matrix}n \\ {k}_{1} , … , {k}_{m}\end{matrix} ) Γ ( \frac{m}{2} ) \frac{{\prod }_{i = 1}^{m} Γ ( {k}_{i} + \frac{1}{2} )}{{π}^{\frac{m}{2}} Γ ( n + \frac{m}{2} )} ,$$

where P_{KT}(t) is the estimated universal probability assignment for a type t,

$$( \begin{matrix}n \\ {k}_{1} , … , {k}_{m}\end{matrix} )$$

is a multinomial coefficient where n and k₁, . . . , kₘ represent parameters of type, m is the number of dimensions, and Π is the product operator, and Γ is the Gamma function. In another example, the code may be a variable length code based on a maximum likelihood probability assignment to each type. For instance, wherein the maximum likelihood probability assignment to each type may be given by

$${P}_{ML} ( t ) = ( \begin{matrix}n \\ {k}_{1} , … , {k}_{m}\end{matrix} ) {( \frac{{k}_{1}}{n} )}^{{k}_{1}} … {( \frac{{k}_{m}}{n} )}^{{k}_{m}}$$

where P_{ML}(t) is the maximum likelihood probability assignment for a type t,

$$( \begin{matrix}n \\ {k}_{1} , … , {k}_{m}\end{matrix} )$$

is a multinomial coefficient where n and k₁, . . . , kₘ represent parameters of a type, and m is the number of dimensions.

According to one implementation of the encoding method, an input image may be obtained and a Gaussian pyramid space of the input image is constructed by applying Gaussian-blur filters to the input image. A difference between two adjacent images is obtained from the Gaussian pyramid to obtain a Gaussian (DoG) space. A keypoint may be identified from the DoG space, from which a gradient distribution is generated for points adjacent to the keypoint. A probability distribution is then generated for the gradient distribution; where this probability distribution is used to obtain the lexicographic index and code. The keypoint may be a local maxima or mimina within the DoG space. A plurality of image gradients may be calculated corresponding to the keypoint, the image gradients being vectors indicating a change in the image in a vicinity of the keypoint.

### Exemplary Mobile Device

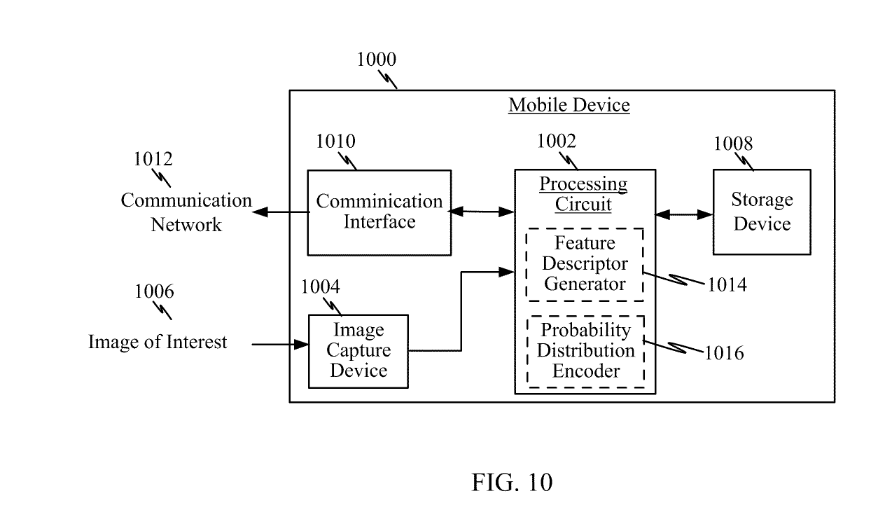

FIG. 10 is a block diagram illustrating an exemplary mobile device adapted to perform probability distribution encoding. The mobile device 1000 may include a processing circuit 1002 coupled to an image capture device 1004, a communication interface 1010 and a storage device 1008. The image capture device 1004 (e.g., digital camera) may be adapted to capture an image of interest 1006 and provides it to the processing circuit 1002. The processing circuit 1002 may be adapted to process the captured image for object recognition. For example, processing circuit may include or implement a feature descriptor generator 1014 that generates one or more feature or keypoint descriptors for the captured image. As part of generating the keypoint descriptors, one or more probability distributions (e.g., gradient histograms) may be generated. The processing circuit may also include or implement a probability distribution encoder 1016 that efficiently compresses the one or more probability distributions. Therefore, the probability distributions may be represented by a type or an index within the keypoint descriptor.

The processing circuit 1002 may then store the one or more feature descriptors in the storage device 1008 and/or may also transmit the feature descriptors over the communication interface 1010 (e.g., a wireless communication interface) through a communication network 1012 to an image matching server that uses the feature descriptors to identify an image or object therein. That is, the image matching server may compare the feature descriptors to its own database of feature descriptors to determine if any image in its database has the same feature(s).

In one example, the probability distribution encoder 1016 may implement one or more methods described herein.

### Exemplary Histogram Decoder

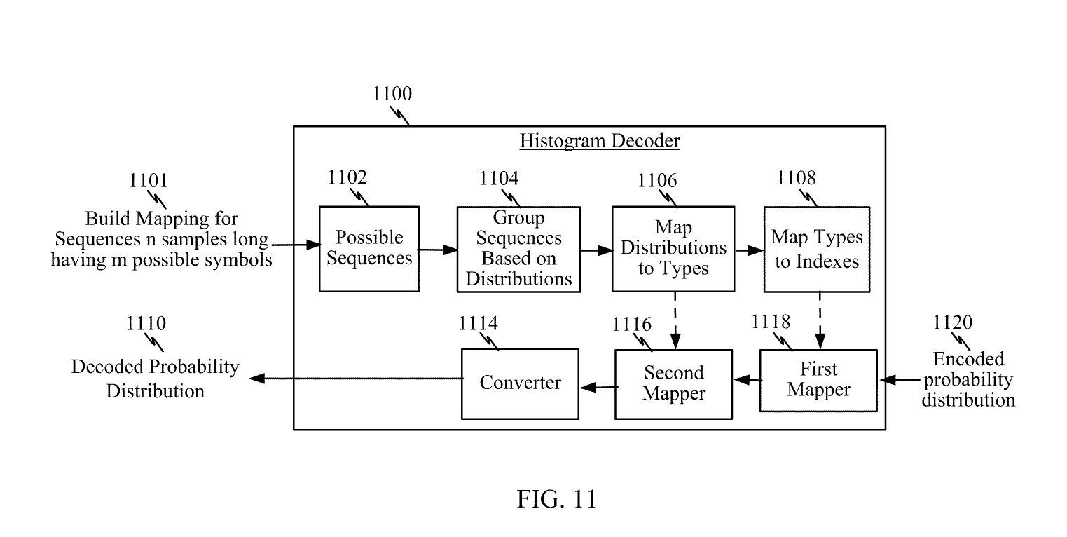

FIG. 11 is a block diagram illustrating an example of a probability distribution decoder 1100. The histogram decoder 1100 may be an independent circuit or module or it may be integrated into another circuit or module. Like the probability distribution encoder 600 (FIG. 6), the probability distribution decoder 1100 may initially build or obtain a mapping of sequences n samples long, the sequence having m possible symbols 1101. First, all possible sequences 1102 (n samples long composed of m possible symbols) is generated. Then, these sequences may be grouped based on their distributions 1104. That is, sequences having the same distributions are grouped together. Then, the different distributions are mapped to a set of types 1106. The types may be further mapped to an index 1108. Note that a corresponding encoder may have corresponding index-to-type and type-to-distribution mappings. These mappings 1106 and 1108 may be done beforehand.

Upon receipt of an encoded probability distribution 1120 (e.g., index), a first mapper 1118 may map the index to a type. A second mapper 1116 may then map the type to a probability distribution. Since the number of samples and m possible symbols and their order are known by the decoder 1100, a converter 1114 may then use the type to generate a decoded probability distribution 1110.

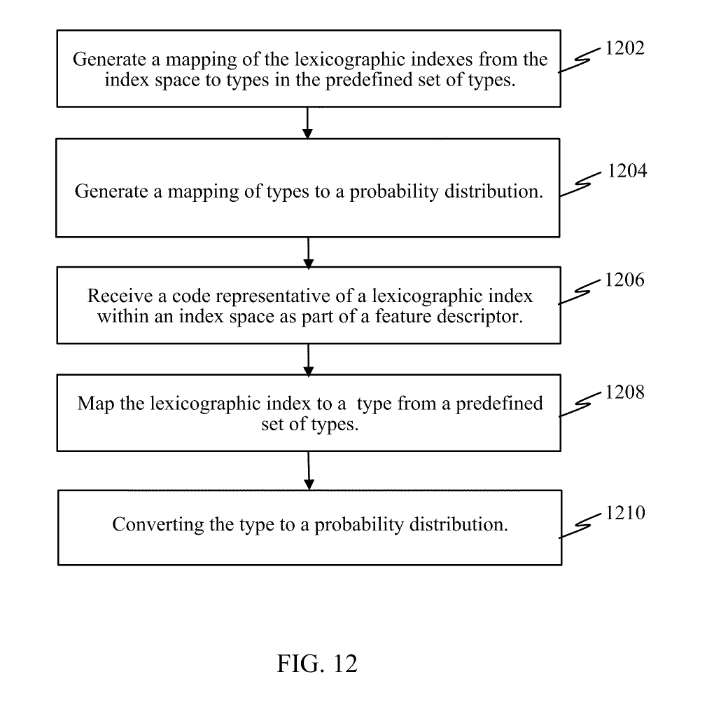

FIG. 12 illustrates a method for decoding probability distributions. A mapping of lexicographic indexes from the index space to types in a predefined set of types may be generated 1202. Additionally, a mapping of types to probability distributions may also be generated 1204. Subsequently, a code representative of a lexicographic index within an index space may be received as part of a feature descriptor 1206. The lexicographic index may be mapped to a type from the predefined set of types 1208. The type may then be converted to a probability distribution 1210. The set of types may be given by a set of rational numbers

$$\{ \frac{{k}_{1}}{n} , … , \frac{{k}_{m}}{n} \} ,$$

where n is a fixed positive integer, and where k₁, . . . , kₘ are non-negative integers, such that

$${\sum }_{i = 1}^{m} {k}_{i} = n ,$$

and where m is the number of dimensions in the probability distribution. The probability distribution may be given by a histogram, wherein the histogram is representative of a gradient distribution for points adjacent to a keypoint for a feature in an image. The set of types may contain M(m, n) possible types,

$$M ( m , n ) = ( \begin{matrix}n + m - 1 \\ m - 1\end{matrix} ) ,$$

where n is the common parameter of types and m is the number of dimensions in the probability distribution
The code may be a fixed-length code presented as a binary representation of the lexicographic index of the type. The code may also be a variable-length code corresponding to a lexicographic index of the type. In one example, the code may be a variable length code based on an estimated universal probability assignment to each type. For instance, the estimated universal probability assignment to each type may be given by

$${P}_{KT} ( t ) = ( \begin{matrix}n \\ {k}_{1} , … , {k}_{m}\end{matrix} ) Γ ( \frac{m}{2} ) \frac{{\prod }_{i = 1}^{m} Γ ( {k}_{i} + \frac{1}{2} )}{{π}^{\frac{m}{2}} Γ ( n + \frac{m}{2} )} ,$$

where P_{KT}(t) is the estimated universal probability assignment for a type t,

$$( \begin{matrix}n \\ {k}_{1} , … , {k}_{m}\end{matrix} )$$

is a multinomial coefficient where n and k₁, . . . , kₘ represent parameters of type, m is the number of dimensions, and Π is the product operator, and Γ is the Gamma function.
In another example, the code may be a variable length code based on a maximum likelihood probability assignment to each type. For instance, the maximum likelihood probability assignment to each type may be given by

$${P}_{ML} ( t ) = ( \begin{matrix}n \\ {k}_{1} , … , {k}_{m}\end{matrix} ) {( \frac{{k}_{1}}{n} )}^{{k}_{1}} … {( \frac{{k}_{m}}{n} )}^{{k}_{m}}$$

where P_{ML}(t) is the maximum likelihood probability assignment for a type t,

$$( \begin{matrix}n \\ {k}_{1} , … , {k}_{m}\end{matrix} )$$

is a multinomial coefficient where n and k₁, . . . , kₘ represent parameters of a type, and m is the number of dimensions.

### Exemplary Image Matching Device

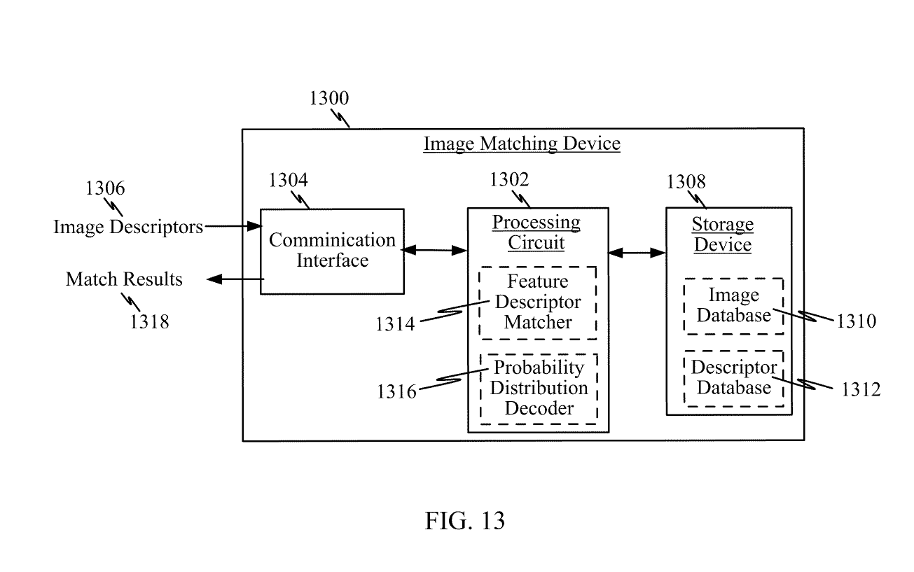

FIG. 13 is a block diagram illustrating an example of an image matching device. The image matching device 1300 may include a processing circuit 1302, coupled to a communication interface 1304 and a storage device 1308. The communication interface 1304 may be adapted to communicate over a network and receive feature descriptors 1306 for an image of interest. The processing circuit 1302 may include an image descriptor matcher 1314 that seeks to match the received image descriptors 1306 with descriptors in an image database 1312. The descriptors in the descriptor database 1312 may correspond to one or more images stored in an image database 1310. Since the received feature descriptors 1306 may include encoded histograms, a probability distribution decoder 1316 may decode the received encoded histograms. The probability distribution decoder 1316 may implement one or more features described herein. Once the histograms are decoded, the feature descriptor matcher 1314 may attempt to determine if the received feature descriptors 1306 match those in the descriptor database 1312. A match result 1318 may be provided via the communication interface 1304 (e.g., to a mobile device that send the feature descriptors 1306).

Coding of types as described herein may be used in virtually any environment, application, or implementation where the shape of some sample-derived distribution is to be communicated and when nothing is known about distribution of such distributions (i.e., such that the encoding considers the worst case scenario).

A particular class of problems to which one or more of the techniques disclosed herein may be applied is coding of distributions in image feature descriptors, such as descriptors generated by CHoG, SIFT, SURF, GLOH, among others. Such feature descriptors are increasingly finding applications in real-time object recognition, 3D reconstruction, panorama stitching, robotic mapping, and/or video tracking. The histogram coding techniques disclosed herein may be applied to such feature descriptors to achieve optimal (or near optimal) lossless and/or lossy compression of histograms or equivalent types of data.

According to one exemplary implementation, an image retrieval application attempts to match a query image to one or more images in an image database. The image database may include millions of feature descriptors associated with the one or more images stored in the database. Compression of such feature descriptors by applying the one or more coding techniques described herein may save significant storage space.

According to yet another exemplary implementation, feature descriptors may be transmitted over a network. System latency may be reduced by applying the one or more coding techniques described herein to compress image features (e.g., compress feature descriptors) thereby sending fewer bits over the network.

According to yet another exemplary implementation, a mobile device may compress feature descriptors for transmission. Because bandwidth tends to be a limiting factor in wireless transmissions, compression of the feature descriptors, by applying the one or more coding techniques described herein, may reduce the amount of data transmitted over wireless channels and backhaul links in a mobile network.

Information and signals may be represented using any of a variety of different technologies and techniques. For example, data, instructions, commands, information, signals and the like that may be referenced throughout the above description may be represented by voltages, currents, electromagnetic waves, magnetic fields or particles, optical fields or particles or any combination thereof.

The various illustrative logical blocks, modules and circuits and algorithm steps described herein may be implemented or performed as electronic hardware, software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. It is noted that the configurations may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed. A process may correspond to a method, a function, a procedure, a subroutine, a subprogram, etc. When a process corresponds to a function, its termination corresponds to a return of the function to the calling function or the main function.

When implemented in hardware, various examples may employ a general purpose processor, a digital signal processor (DSP), an application specific integrated circuit (ASIC), a field programmable gate array signal (FPGA) or other programmable logic device, discrete gate or transistor logic, discrete hardware components or any combination thereof designed to perform the functions described herein. A general purpose processor may be a microprocessor, but in the alternative, the processor may be any conventional processor, controller, microcontroller or state machine. A processor may also be implemented as a combination of computing devices, e.g., a combination of a DSP and a microprocessor, a plurality of microprocessors, one or more microprocessors in conjunction with a DSP core or any other such configuration.

When implemented in software, various examples may employ firmware, middleware or microcode. The program code or code segments to perform the necessary tasks may be stored in a computer-readable medium such as a storage medium or other storage(s). A processor may perform the necessary tasks. A code segment may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc. may be passed, forwarded, or transmitted via any suitable means including memory sharing, message passing, token passing, network transmission, etc.

As used in this application, the terms “component,” “module,” “system,” and the like are intended to refer to a computer-related entity, either hardware, firmware, a combination of hardware and software, software, or software in execution. For example, a component may be, but is not limited to being, a process running on a processor, a processor, an object, an executable, a thread of execution, a program, and/or a computer. By way of illustration, both an application running on a computing device and the computing device can be a component. One or more components can reside within a process and/or thread of execution and a component may be localized on one computer and/or distributed between two or more computers. In addition, these components can execute from various computer readable media having various data structures stored thereon. The components may communicate by way of local and/or remote processes such as in accordance with a signal having one or more data packets (e.g., data from one component interacting with another component in a local system, distributed system, and/or across a network such as the Internet with other systems by way of the signal).

In one or more examples herein, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media. Software may comprise a single instruction, or many instructions, and may be distributed over several different code segments, among different programs and across multiple storage media. An exemplary storage medium may be coupled to a processor such that the processor can read information from, and write information to, the storage medium. In the alternative, the storage medium may be integral to the processor.

The methods disclosed herein comprise one or more steps or actions for achieving the described method. The method steps and/or actions may be interchanged with one another without departing from the scope of the claims. In other words, unless a specific order of steps or actions is required for proper operation of the embodiment that is being described, the order and/or use of specific steps and/or actions may be modified without departing from the scope of the claims.

One or more of the components, steps, and/or functions illustrated in the Figures may be rearranged and/or combined into a single component, step, or function or embodied in several components, steps, or functions. Additional elements, components, steps, and/or functions may also be added. The apparatus, devices, and/or components illustrated in Figures may be configured or adapted to perform one or more of the methods, features, or steps described in other Figures. The algorithms described herein may be efficiently implemented in software and/or embedded hardware for example.

It should be noted that the foregoing configurations are merely examples and are not to be construed as limiting the claims. The description of the configurations is intended to be illustrative, and not to limit the scope of the claims. As such, the present teachings can be readily applied to other types of apparatuses and many alternatives, modifications, and variations will be apparent to those skilled in the art.

What is claimed is:

1. A method for encoding a probability distribution, comprising:
quantizing a probability distribution as a type from a predefined set of types;
mapping the type to a lexicographic index from an index space that spans the predefined set of types; and
transmitting a code for the lexicographic index as part of a feature descriptor.

2. The method of claim 1, wherein the set of types is given by a set of rational numbers
$$\{ \frac{{k}_{1}}{n} , … , \frac{{k}_{m}}{n} \} ,$$
where n is a fixed positive integer, and where k₁, . . . , kₘ are non-negative integers, such that
$${\sum }_{i = 1}^{m} {k}_{i} = n ,$$
and where m is the number of dimensions in the probability distribution.

3. The method of claim 1, further comprising:
generating a mapping of probability distributions of samples to the types from the predefined set of types;
generating a mapping of the types in the predefined set of types to lexicographic indexes from the index space.

4. The method of claim 1, wherein the probability distribution is given by a histogram.

5. The method of claim 1, wherein the set of types contains M(m, n) possible types,
$$M ( m , n ) = ( \begin{matrix}n + m - 1 \\ m - 1\end{matrix} ) ,$$
where n is the common parameter of types and m is the number of dimensions in the probability distribution.

6. The method of claim 1, wherein the code is a fixed-length code presented as a binary representation of the lexicographic index of the type.

7. The method of claim 2, wherein the code is a variable-length code corresponding to a lexicographic index of the type.

8. The method of claim 7, wherein the code is a variable length code based on an estimated universal probability assignment to each type.

9. The method of claim 8, wherein the estimated universal probability assignment to each type is given by
$${P}_{KT} ( t ) = ( \begin{matrix}n \\ {k}_{1} , … , {k}_{m}\end{matrix} ) Γ ( \frac{m}{2} ) \frac{{\prod }_{i = 1}^{m} Γ ( {k}_{i} + \frac{1}{2} )}{{π}^{\frac{m}{2}} Γ ( n + \frac{m}{2} )} ,$$
where P_{KT}(t) is the estimated universal probability assignment for a type t,
$$( \begin{matrix}n \\ {k}_{1} , … , {k}_{m}\end{matrix} )$$
is a multinomial coefficient where n and k₁, . . . , kₘ represent parameters of type, m is the number of dimensions, and Π is the product operator, and Γ is the Gamma function.

10. The method of claim 7, wherein the code is a variable length code based on a maximum likelihood probability assignment to each type.

11. The method of claim 10, wherein the maximum likelihood probability assignment to each type is given by
$${P}_{ML} ( t ) = ( \begin{matrix}n \\ {k}_{1} , … , {k}_{m}\end{matrix} ) {( \frac{{k}_{1}}{n} )}^{{k }_{1}} … {( \frac{{k}_{m}}{n} )}^{{k}_{m}}$$
where P_{ML}(t) is the maximum likelihood probability assignment for a type t,
$$( \begin{matrix}n \\ {k}_{1} , … , {k}_{m}\end{matrix} )$$
is a multinomial coefficient where n and k₁, . . . , kₘ represent parameters of a type, and m is the number of dimensions.

12. The method of claim 1, further comprising:
obtaining an input image;
constructing a Gaussian pyramid space of the input image by applying Gaussian-blur filters to the input image;
obtaining a difference between two adjacent images from the Gaussian pyramid to obtain a Gaussian (DoG) space;
identify a keypoint from the DoG space;
generating a gradient distribution for points adjacent to the keypoint; and
generating the probability distribution for the gradient distribution.

13. The method of claim 12, wherein the keypoint is a local maxima or mimina within the DoG space.

14. The method of claim 12, further comprising:
calculating a plurality of image gradients corresponding to the keypoint, the image gradients being vectors indicating a change in the image in a vicinity of the keypoint.

15. An encoding device, comprising:
a quantizer adapted to quantize a probability distribution as a type from a predefined set of types;
a mapper adapted to map the type to a lexicographic index from an index space that spans the predefined set of types; and
a communication interface adapted to transmit a code for the lexicographic index as part of a feature descriptor.

16. The encoding device of claim 15, wherein the set of types is given by a set of rational numbers
$$\{ \frac{{k}_{1}}{n} , … , \frac{{k}_{m}}{n} \} ,$$
where n is a fixed positive integer, and where k₁, . . . , kₘ are non-negative integers, such that
$${\sum }_{i = 1}^{m} {k}_{i} = n ,$$
and where m is the number of dimensions in the probability distribution.

17. The encoding device of claim 15, further comprising:
a first map generator adapted to generate a mapping of probability distributions of samples to the types from the predefined set of types;
a second map generator adapted to generate a mapping of the types in the predefined set of types to lexicographic indexes from the index space.

18. The encoding device of claim 15, wherein the probability distribution is given by a histogram.

19. The encoding device of claim 15, wherein the set of types contains M(m, n) possible types,
$$M ( m , n ) = ( \begin{matrix}n + m - 1 \\ m - 1\end{matrix} ) ,$$
where n is the common parameter of types and m is the number of dimensions in the probability distribution.

20. The encoding device of claim 15, wherein the code is a fixed-length code presented as a binary representation of the lexicographic index of the type.

21. The encoding device of claim 16, wherein the code is a variable-length code corresponding to a lexicographic index of the type.

22. The encoding device of claim 21, wherein the code is a variable length code based on an estimated universal probability assignment to each type.

23. The encoding device of claim 22, wherein the estimated universal probability assignment to each type is given by
$${P}_{KT} ( t ) = ( \begin{matrix}n \\ {k}_{1} , … , {k}_{m}\end{matrix} ) Γ ( \frac{m}{2} ) \frac{{\prod }_{i = 1}^{m} Γ ( {k}_{i} + \frac{1}{2} )}{{π}^{\frac{m}{2}} Γ ( n + \frac{m}{2} )} ,$$
where P_{KT}(t) is the estimated universal probability assignment for a type t,
$$( \begin{matrix}n \\ {k}_{1} , … , {k}_{m}\end{matrix} )$$
is a multinomial coefficient where n and k₁, . . . , kₘ represent parameters of type, m is the number of dimensions, and Π is the product operator, and Γ is the Gamma function.

24. The encoding device of claim 21, wherein the code is a variable length code based on a maximum likelihood probability assignment to each type.

25. The encoding device of claim 24, wherein the maximum likelihood probability assignment to each type is given by
$${P}_{ML} ( t ) = ( \begin{matrix}n \\ {k}_{1} , … , {k}_{m}\end{matrix} ) {( \frac{{k}_{1}}{n} )}^{{k }_{1}} … {( \frac{{k}_{m}}{n} )}^{{k}_{m}}$$
where P_{ML}(t) is the maximum likelihood probability assignment for a type t,
$$( \begin{matrix}n \\ {k}_{1} , … , {k}_{m}\end{matrix} )$$
is a multinomial coefficient where n and k₁, . . . , kₘ represent parameters of a type, and m is the number of dimensions.

26. An encoding device, comprising:
means for quantizing a probability distribution as a type from a predefined set of types;
means for mapping the type to a lexicographic index from an index space that spans the predefined set of types; and
means for transmitting a code for the lexicographic index as part of a feature descriptor.

27. The encoding device of claim 26, wherein the set of types is given by a set of rational numbers
$$\{ \frac{{k}_{1}}{n} , … , \frac{{k}_{m}}{n} \} ,$$
where n is a fixed positive integer, and where k₁, . . . , kₘ are non-negative integers, such that
$${\sum }_{i = 1}^{m} {k}_{i} = n ,$$
and where m is the number of dimensions in the probability distribution.

28. The encoding device of claim 26, wherein the set of types contains M(m, n) possible types,
$$M ( m , n ) = ( \begin{matrix}n + m - 1 \\ m - 1\end{matrix} ) ,$$
where n is the common parameter of types and m is the number of dimensions in the probability distribution.

29. A machine-readable medium comprising instructions operational for encoding a probability distribution, which when executed by a processor causes the processor to:
quantize a probability distribution as a type from a predefined set of types;
map the type to a lexicographic index from an index space that spans the predefined set of types; and
transmit a code for the lexicographic index as part of a feature descriptor.

30. The machine-readable medium of claim 29, further comprising instructions which when executed by a processor causes the processor to:
generate a mapping of probability distributions of samples to the types from the predefined set of types;
generate a mapping of the types in the predefined set of types to lexicographic indexes from the index space.

31. A method for decoding a probability distribution, comprising:
receiving a code representative of a lexicographic index within an index space as part of a feature descriptor;
mapping the lexicographic index to a type from a predefined set of types; and
converting the type to a probability distribution.

32. The method of claim 31, wherein the set of types is given by a set of rational numbers
$$\{ \frac{{k}_{1}}{n} , … , \frac{{k}_{m}}{n} \} ,$$
where n is a fixed positive integer, and where k₁, . . . , kₘ are non-negative integers, such that
$${\sum }_{i = 1}^{m} {k}_{i} = n ,$$
and where m is the number of dimensions in the probability distribution.

33. The method of claim 31, further comprising:
generating a mapping of the lexicographic indexes from the index space to types in the predefined set of types; and
generating a mapping of types to probability distributions.

34. The method of claim 31, wherein the probability distribution is given by a histogram, wherein the histogram is representative of a gradient distribution for points adjacent to a keypoint for a feature in an image.

35. The method of claim 31, wherein the set of types contains M(m, n) possible types, where
$$M ( m , n ) = ( \begin{matrix}n + m - 1 \\ m - 1\end{matrix} ) ,$$
n is the common parameter of types and m is the number of dimensions in the probability distribution.

36. The method of claim 31, wherein the code is a fixed-length code presented as a binary representation of the lexicographic index of the type.

37. The method of claim 32, wherein the code is a variable-length code corresponding to a lexicographic index of the type.

38. The method of claim 37, wherein the code is a variable length code based on an estimated universal probability assignment to each type.

39. The method of claim 38, wherein the estimated universal probability assignment to each type is given by
$${P}_{KT} ( t ) = ( \begin{matrix}n \\ {k}_{1} , … , {k}_{m}\end{matrix} ) Γ ( \frac{m}{2} ) \frac{{\prod }_{i = 1}^{m} Γ ( {k}_{i} + \frac{1}{2} )}{{π}^{\frac{m}{2}} Γ ( n + \frac{m}{2} )} ,$$
where P_{KT}(t) is the estimated universal probability assignment for a type t,
$$( \begin{matrix}n \\ {k}_{1} , … , {k}_{m}\end{matrix} )$$
is a multinomial coefficient where n and k₁, . . . , kₘ represent parameters of type, m is the number of dimensions, and Π is the product operator, and Γ is the Gamma function.

40. The method of claim 37, wherein the code is a variable length code based on a maximum likelihood probability assignment to each type.

41. The method of claim 40, wherein the maximum likelihood probability assignment to each type is given by
$${P}_{ML} ( t ) = ( \begin{matrix}n \\ {k}_{1} , … , {k}_{m}\end{matrix} ) {( \frac{{k}_{1}}{n} )}^{{k}_{1}} … {( \frac{{k}_{m}}{n} )}^{{k}_{m}}$$
where P_{ML}(t) is the maximum likelihood probability assignment for a type t,
$$( \begin{matrix}n \\ {k}_{1} , … , {k}_{m}\end{matrix} )$$
is a multinomial coefficient where n and k₁, . . . , kₘ represent parameters of a type, and m is the number of dimensions.

42. A decoding device, comprising
a receiver for receiving a code representative of a lexicographic index within an index space as part of a feature descriptor;
a first mapper for mapping the lexicographic index to a type from a predefined set of types; and
a converter for converting the type to a probability distribution.

43. The decoding device of claim 42, wherein the set of types is given by a set of rational numbers
$$\{ \frac{{k}_{1}}{n} , … , \frac{{k}_{m}}{n} \} ,$$
where n is a fixed positive integer, and where k₁, . . . , kₘ are non-negative integers, such that
$${\sum }_{i = 1}^{m} {k}_{i} = n ,$$
and where m is the number of dimensions in the probability distribution.

44. The decoding device of claim 42, wherein the probability distribution is given by a histogram, wherein the histogram is representative of a gradient distribution for points adjacent to a keypoint for a feature in an image.

45. The decoding device of claim 42, wherein the set of types contains M(m, n) possible types,
$$M ( m , n ) = ( \begin{matrix}n + m - 1 \\ m - 1\end{matrix} ) ,$$
where n is the common parameter of types and m is the number of dimensions in the probability distribution.

46. The decoding device of claim 42, wherein the code is a fixed-length code presented as a binary representation of the lexicographic index of the type.

47. The decoding device of claim 43, wherein the code is a variable-length code corresponding to a lexicographic index of the type.

48. The decoding device of claim 47, wherein the code is a variable length code based on an estimated universal probability assignment to each type.

49. The decoding device of claim 48, wherein the estimated universal probability assignment to each type is given by
$${P}_{KT} ( t ) = ( \begin{matrix}n \\ {k}_{1} , … , {k}_{m}\end{matrix} ) Γ ( \frac{m}{2} ) \frac{{\prod }_{i = 1}^{m} Γ ( {k}_{i} + \frac{1}{2} )}{{π}^{\frac{m}{2}} Γ ( n + \frac{m}{2} )} ,$$
where P_{KT}(t) is the estimated universal probability assignment for a type t,
$$( \begin{matrix}n \\ {k}_{1} , … , {k}_{m}\end{matrix} )$$
is a multinomial coefficient where n and k₁, . . . , kₘ represent parameters of type, m is the number of dimensions, and Π is the product operator, and Γ is the Gamma function.

50. The decoding device of claim 47, wherein the code is a variable length code based on a maximum likelihood probability assignment to each type.

51. The decoding device of claim 50, wherein the maximum likelihood probability assignment to each type is given by
$${P}_{ML} ( t ) = ( \begin{matrix}n \\ {k}_{1} , … , {k}_{m}\end{matrix} ) {( \frac{{k}_{1}}{n} )}^{{k}_{1}} … {( \frac{{k}_{m}}{n} )}^{{k}_{m}}$$
where P_{ML}(t) is the maximum likelihood probability assignment for a type t,
$$( \begin{matrix}n \\ {k}_{1} , … , {k}_{m}\end{matrix} )$$
is a multinomial coefficient where n and k₁, . . . , kₘ represent parameters of a type, and m is the number of dimensions.

52. A decoding device, comprising
means for receiving a code representative of a lexicographic index within an index space as part of a feature descriptor;
means for mapping the lexicographic index to a type from a predefined set of types; and
means for converting the type to a probability distribution.

53. The decoding device of claim 52, wherein the set of types is given by a set of rational numbers
$$\{ \frac{{k}_{1}}{n} , … , \frac{{k}_{m}}{n} \} ,$$
where n is a fixed positive integer, and where k₁, . . . , kₘ are non-negative integers, such that
$${\sum }_{i = 1}^{m} {k}_{i} = n ,$$
and where m is the number of dimensions in the probability distribution.

54. The decoding device of claim 52, wherein the probability distribution is given by a histogram, wherein the histogram is representative of a gradient distribution for points adjacent to a keypoint for a feature in an image.

55. A machine-readable medium comprising instructions operational for decoding a probability distribution, which when executed by a processor causes the processor to:
receive a code representative of a lexicographic index within an index space as part of a feature descriptor;
map the lexicographic index to a type from a predefined set of types; and
convert the type to a probability distribution.

56. The machine-readable medium of claim 55, further comprising instructions which when executed by a processor causes the processor to:
generate a mapping of the lexicographic indexes from the index space to types in the predefined set of types; and
generate a mapping of types to probability distributions.
